(19) United States
(12) Patent Application Publication
(10) Pub. No.: US 2003/0205949 A1
(43) Pub. Date: Nov. 6, 2003

(54) METHOD AND APPARATUS FOR DRIVING A PLURAL BANK PIEZOELECTRIC FUEL INJECTOR ELEMENT WITH BANK-SELECTION SWITCHES AND TRIAC DRIVE CIRCUIT

(76) Inventors: Johannes-Jorg Rueger, Vaihingen/enz (DE); Joerg Reineke, Stuttgart (DE)

Correspondence Address: KENYON & KENYON, ONE BROADWAY, NEW YORK, NY, 10004, US

(21) Appl. No.: 09/824,191

(22) Filed: Apr. 2, 2001

(30) Foreign Application Priority Data
Apr. 1, 2000 (EP) 00 106 988.9

(51) Int. Cl. H01L 41/04

(52) U.S. Cl. 310/316.03; 310/316.01; 310/328

(57) ABSTRACT

The invention describes a method and an apparatus for driving fuel injectors divided into a plurality of injector banks, each bank containing at least one piezoelectric element, each bank being selected for charging or discharging by a bank-selection switch. The apparatus is characterized in that a bank selection switch includes a triac with a triac drive circuit.

The present invention relates to an apparatus as defined in the preamble of claim 1, and a method as defined in the preamble of claim 7, i.e. a method and an apparatus for driving piezoelectric fuel injector elements divided into a plurality of injector banks, each bank containing at least one piezoelectric element used as an fuel injector actuator.

The present piezoelectric elements being considered in more detail are, in particular but not exclusively, piezoelectric elements used as actuators. Piezoelectric elements can be used for such purposes because, as is known, they possess the property of contracting or expanding as a function of a voltage applied thereto or occurring therein.

The practical implementation of actuators using piezoelectric elements proves to be advantageous in particular if the actuator in question must perform rapid and/or frequent movements.

The use of piezoelectric elements as actuators proves to be advantageous, inter alia, in fuel injection nozzles for internal combustion engines. Reference is made, for example, to EP 0 371 469 B1 and to EP 0 379 182 B1 regarding the usability of piezoelectric elements in fuel injection nozzles.

Piezoelectric elements are capacitative elements which, as already partially alluded to above, contract and expand in accordance with the particular charge state or the voltage occurring therein or applied thereto. In the example of a fuel injection nozzle, expansion and contraction of piezoelectric elements is used to control valves that manipulate the linear strokes of injection needles.

In case of a fuel injection system with multiple-acting valves, the multiple-acting valves are used to execute the opening and the closing of the fuel injection nozzles. A piezoelectric element may be used to actuate the multiple-acting valve.

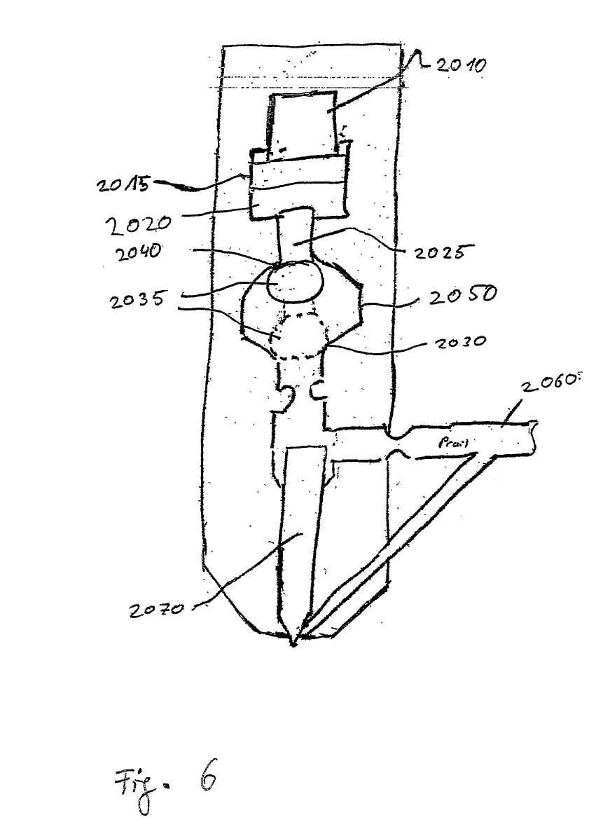

FIG. 6 is a schematic representation of a fuel injection system using a piezoelectric element 2010 as an actuator. Referring to FIG. 6, the piezoelectric element 2010 is electrically energized to expand and contract in response to a given activation voltage. The piezoelectric element 2010 is coupled to a piston 2015. In the expanded state, the piezoelectric element 2010 causes the piston 2015 to protrude into a hydraulic adapter 2020 which contains a hydraulic fluid, for example fuel. As a result of the piezoelectric element's expansion, a double acting control valve 2025 is hydraulically pushed away from hydraulic adapter 2020 and the valve plug 2035 is extended away from a first closed position 2040. The combination of double acting control valve 2025 and hollow bore 2050 is often referred to as double acting, double seat valve for the reason that when piezoelectric element 2010 is in an unexcited state, the double acting control valve 2025 rests in its first closed position 2040. On the other hand, when the piezoelectric element 2010 is fully extended, it rests in its second closed position 2030. The later position of valve plug 2035 is schematically represented with ghost lines in FIG. 6.

The fuel injection system comprises an injection needle 2070 allowing for injection of fuel from a pressurized fuel supply line 2060 into the cylinder (not shown). When the piezoelectric element 2010 is unexcited or when it is fully extended, the double acting control valve 2025 rests respectively in its first closed position 2040 or in its second closed position 2030. In either case, the hydraulic rail pressure maintains injection needle 2070 at a closed position. Thus, the fuel mixture does not enter into the cylinder (not shown). Conversely, when the piezoelectric element 2010 is excited such that double acting control valve 2025 is in the so-called mid-position with respect to the hollow bore 2050, then there is a pressure drop in the pressurized fuel supply line 2060. This pressure drop results in a pressure differential in the pressurized fuel supply line 2060 between the top and the bottom of the injection needle 2070 so that the injection needle 2070 is lifted allowing for fuel injection into the cylinder (not shown).

A more detailed description of a corresponding system can be found at German patent application Nos. DE 197 42 073 A1 and DE 1976 29 844 A1, which are hereby incorporated by reference herein in their entirety. These patent applications disclose piezoelectric elements with double acting, double seat valves for controlling injection needles in a fuel injection system.

In a fuel injection nozzle implemented as a double acting, double seat valve to control linear stroke of a needle for fuel injection into a cylinder of an internal combustion engine, the amount of fuel injected into a corresponding cylinder is a function of the time the valve is open, and in the case of the use of a piezoelectric element, an activation voltage applied to the piezoelectric element.

In the example of a double acting control valve, the piezoelectric element is to be expanded or contracted by the effect of an activation voltage so that a controlled valve plug is positioned midway between the two seats of the double seat valve to position the corresponding injection needle for maximum fuel flow during a set time period.

When driving the injectors of an engine with a common rail system, there is a certain probability that overlapping fuel injection operations will be required in certain engine speed ranges. This probability increases with the number of cylinders. This means, for example, that during main fuel injection on an initial cylinder, pilot injection or post injection is being performed on another cylinder.

Therefore, usually the actuators are divided into two banks each having one or more piezoelectric elements in parallel, with bank select switches for selecting the bank that is to be charged or discharged.

In previous systems, the bank select switches were implemented as semiconductor switches (e.g. IGBT or MOSFET switches) that either conducted or blocked current in one direction, depending on the drive signal. A back-to-back diode connection operated in the other current direction.

In the case of certain errors or defects in known configurations, however, it is not possible to continue operating the output stage because a defective bank cannot be shutdown. An example of such a defect is a short circuit of an actuator supply lead to the chassis ground. Thus, with prior systems, to ensure limited operation in this case with the remaining bank, the entire output stage must be duplicated. This would require additional circuitry, space and cost.

Furthermore, due to the two-bank structure, overlapping injections, i.e., overlapping voltage shapes, may only be achieved on two injectors of different banks, but not on the same bank. For certain requirements this significantly limits the flexibility of the injection system. This limitation again requires additional circuitry, space and cost to overcome.

It is therefore an object of the present invention to provide the apparatus as defined in the preamble of claim 1 and the method as defined in the preamble of claim 7 in such a way that these limitations can be overcome, i.e., to provide an apparatus in which:

it is possible to drive at least the other bank, or banks for systems with more than two banks, even in the presence of an error on one bank; and

overlapping voltage shapes of injectors for any two or more injectors is made possible by providing a separate bank for each cylinder of the engine.

These goals should be achieved with low or no additional, or even reduced, costs and space requirements.

This object is achieved, according to the present invention, by way of the features claimed in the characterizing portion of claim 1 (apparatus) and in the characterizing portion of claim 7 (method).

The present invention provides for:

designing the bank select switches S1 and S2 (or any bank select switches) as triacs; and

shutting down the injector bank when the triac drive circuit is not driven; or

providing one bank select switch for each cylinder as a triac and providing a main switch as an IGBT or a MOSFET, in which case cylinder select switches are not employed.

Embodiments of the present invention make it possible to shut down a defective piezoelectric actuator, or bank of actuators, by using a special type of switch in place of the previous select switches. In the event of an error or defect, operation of the other banks is possible independently, and emergency operation of the fuel injection system and of the engine is also possible, thereby preventing a total failure of the vehicle.

Furthermore, in another embodiment of the present invention, bank cylinder switches are not employed and an additional main switch is included in the circuitry. This makes is possible to realize overlapping voltage shapes for any cylinders.

Additionally, in an embodiment of the present invention one bank selector switch is provided for each cylinder. This permits the realization of overlapping voltage shapes and therefore overlapping injections on any two or more cylinders.

The present invention in some embodiments requires fewer electrical components for implementation, thereby saving cost and space.

Advantageous developments of the present invention are evident from the dependent claims, the description below, and the figures.

The invention will be explained below in more detail with reference to exemplary embodiments, referring to the figures in which:

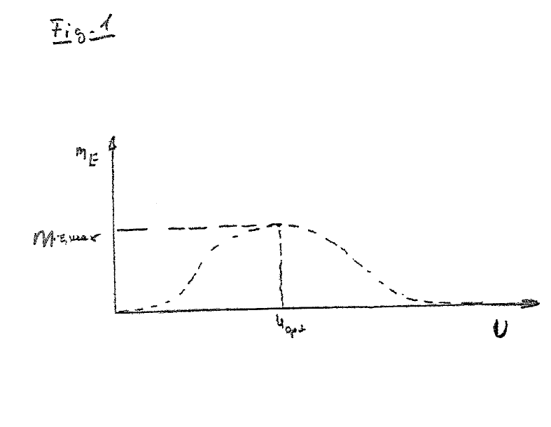

FIG. 1 shows a graph depicting the relationship between activation voltage and injected fuel volume in a fixed time period for a double acting control valve;

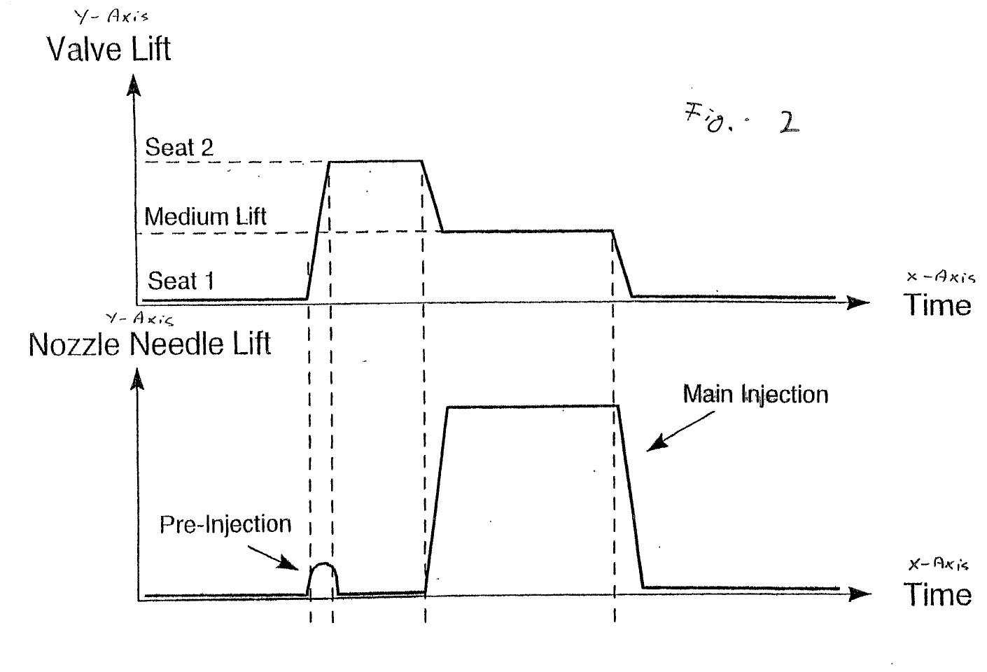

FIG. 2 shows a schematic profile of an exemplary control valve stroke;

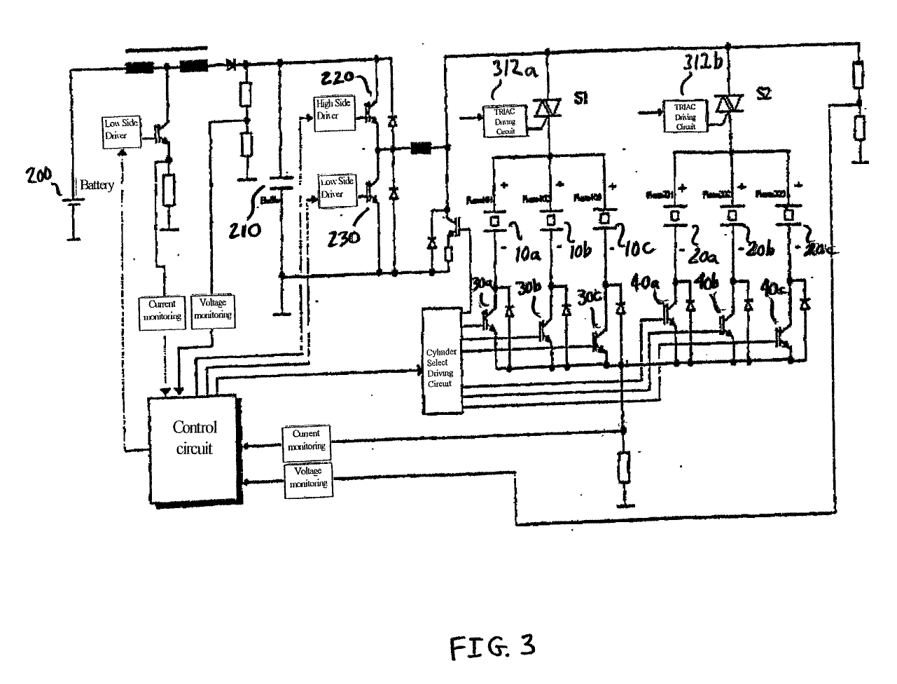

FIG. 3 shows a schematic diagram of an exemplary piezoelectric element control system according to the present invention;

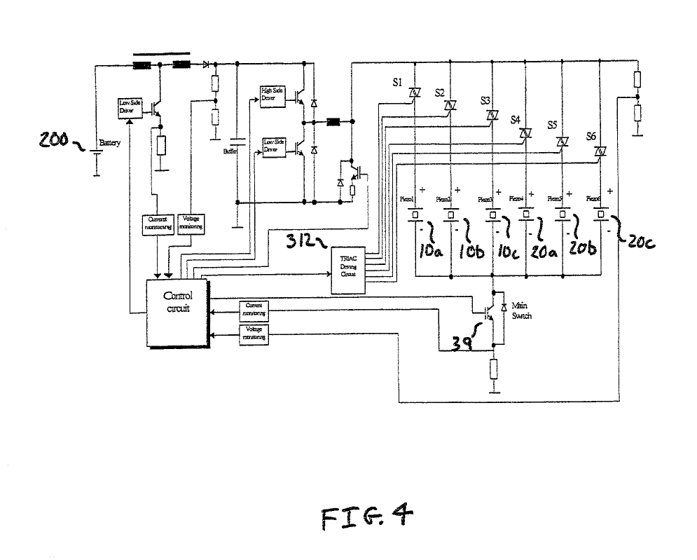

FIG. 4 shows another embodiment of a piezoelectric element control system according to the present invention;

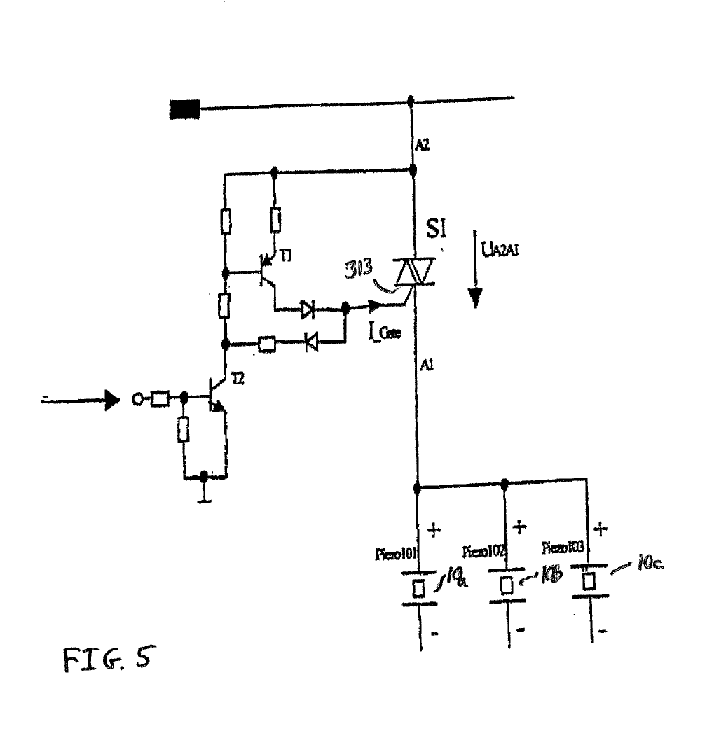

FIG. 5 shows a schematic profile of a triac switch, including its drive circuit, for a bank of piezoelectric elements; and

FIG. 6 shows a schematic representation of an exemplary fuel injection system using a piezoelectric element as an actuator.

FIG. 1 shows a graph depicting the relationship between activation voltage U and injected fuel volume m_{E} during a preselected fixed time period, for an exemplary fuel injection system using piezoelectric elements acting upon double seat control valves. The y-axis represents volume of fuel injected into a cylinder chamber during the preselected fixed period of time. The x-axis represents the activation voltage applied to or stored in the corresponding piezoelectric element, used to displace a valve plug of the double seat control valve.

At x=0, y=0, the activation voltage U is zero, and the valve plug is seated in a first closed version to prevent the flow of fuel during the preselected fixed period of time. For values of the activation voltage greater than zero, up to the x-axis point indicated as Uₒₚₜ, the represented values of the activation voltage U cause the displacement of the valve plug away from the first seat and towards the second seat, in a manner that results in a greater volume of injected fuel for the fixed time period, as the activation voltage approaches Uₒₚₜ, up to the value for volume indicted on the y-axis by m_{E,max}. The point m_{E,max}, corresponding to the greatest volume for the injected fuel during the fixed period of time, represents the value of the activation voltage for application to or charging of the piezoelectric element, that results in an optimal displacement of the valve plug between the first and second valve seats.

As shown on the graph of FIG. 1, for values of the activation voltage greater than Uₒₚₜ, the volume of fuel injected during the fixed period of time decrease until it reaches zero. This represents displacement of the valve plug from the optimal point and toward the second seat of the double acting control valve until the valve plug is seated in its second closed position. Thus, the graph of FIG. 1 illustrates that a maximum volume of fuel injection occurs when the activation voltage causes the piezoelectric element to displace the valve plug to the optimal point.

The present invention teaches that the value for Uₒₚₜ at any given time for a particular piezoelectric element is influenced by the operating characteristics of the particular piezoelectric element at that time. That is, the amount of displacement caused by the piezoelectric element for a certain activation voltage varies as a function of the operating characteristics of the particular piezoelectric element. Accordingly, in order to achieve a maximum volume of fuel injection, m_{E,max}, during a given fixed period of time, the activation voltage applied to or occurring in the piezoelectric element should be set to a value relevant to current operating characteristics of the particular piezoelectric element, to achieve Uₒₚₜ.

FIG. 2 shows a double graph representing a schematic profile of an exemplary control valve stroke, to illustrate the double seat valve operation discussed above. In the upper graph of FIG. 2, the x-axis represents time, and the y-axis represents displacement of the valve plug (valve lift). In the lower graph of FIG. 2, the x-axis once again represents time, while the y-axis represents a nozzle needle lift to provide fuel flow, resulting from the valve lift of the upper graph. The upper and lower graphs are aligned with one another to coincide in time, as represented by the respective x-axises.

During an injection cycle, the piezoelectric element is charged resulting in an expansion of the piezoelectric element, as will be described in greater detail, and causing the corresponding valve plug to move from the first seat to the second seat for a pre-injection stroke, as shown in the upper graph of FIG. 2. The lower graph of FIG. 2 shows a small injection of fuel that occurs as the valve plug moves between the two seats of the double seat valve, opening and closing the valve as the plug moves between the seats. In general, the charging of the piezoelectric element can be done in two steps: the first one is to charge it to a certain voltage and cause the valve to open and the second one is to charge it further and cause the valve to close again at the second seat. Between these steps, in general, there can be a certain time delay.

After a preselected period of time, a discharging operation is then performed, as will be explained in greater detail below, to reduce the charge within the piezoelectric element so that it contracts, as will also be described in greater detail, causing the valve plug to move away from the second seat, and hold at a midway point between the two seats. As indicated in FIG. 1, the activation voltage within the piezoelectric element is to reach a value that equals Uₒₚₜ to correspond to an optimal point of the valve lift, and thereby obtain a maximum fuel flow, m_{E,max}, during the period of time allocated to a main injection. The upper and lower graphs of FIG. 2 show the holding of the valve lift at a midway point, resulting in a main fuel injection.

At the end of the period of time for the main injection, the piezoelectric element is discharged to an activation voltage of zero, resulting in further contraction of the piezoelectric element, to cause the valve plug to move away from the optimal position, towards the first seat, closing the valve and stopping fuel flow, as shown in the upper and lower graphs of FIG. 2. At this time, the valve plug will once again be in a position to repeat another pre-injection, main injection cycle, as just described above, for example. Of course, any other injection cycle can be performed.

Referring to FIG. 3, an embodiment of the present invention in which the bank select switches S1 and S2 drive banks of piezoelectric elements 10, 20, wherein each bank contains more than one element 10a-10c, 20a-20c, and wherein each bank select switch is designed as a triac is shown. Triac driving circuits 312a, 312b are provided for driving switches S1 and S2, respectively. As embodied herein, each piezoelectric element actuates an injection valve of a corresponding respective cylinder of an internal combustion engine. Cylinder select switches 30, 40 are provided for selectively controlling a given respective piezoelectric element 10, 20. As would be understood by one of skill in the art, battery 200 and capacitor 210 are used to charge and discharge piezoelectric elements 10, 20 via charging switch 220 and discharging switch 230, respectively.

Referring to FIG. 4, in another embodiment of the present invention, a bank select switch S1-S6 is provided for each respective cylinder. As in FIG. 3, bank select switches S1-S6 are implemented as triacs, with triac driving circuit 312 being provided for driving the triacs. No cylinder select switches 30, 40 (FIG. 3) are required. In this embodiment each cylinder has its own piezoelectric element bank 10a-10c, 20a-20c, permitting maximum flexibility in control of the piezoelectric elements.

To avoid damage upon the occurrence of an error, such as a short to battery voltage, main switch 39 is provided lowside. Main switch 39 may be an IGBT or a MOSFET. Upon a short to battery voltage, when selecting a triac (S1-S6), main switch 39 cannot be easily opened again by a drive circuit.

Referring to FIG. 5 the drive circuit of the triac switch S1 is shown. This circuit must be provided once for each bank of piezoelectric elements 10. Voltages of either polarity can be applied to switch S1 (U_{A2A1}). When not triggered, the triac S1 blocks the connected bank, i.e., piezoelectric elements 10a-10c in FIG. 3, and the connected bank cannot be operated. The triac does not conduct until a specific firing current is flowing at gate 313. When used as a bank select switch, reliable drive for the triac is necessary. The reasons for this are two-fold. First, reliable drive is necessary to prevent an unintended firing, regardless of the polarity of the main line (A1, A2). Second, reliable drive makes possible reliable switch-on during both the charging process (current flowing from A2 to A1) and during the discharging process (current flowing from A1 to A2).

One particular advantage of the invention is the drive circuit of the triac. The drive circuit is specially adapted for use in the piezoelectric output stage, and is very simply designed with two transistors T1, T2, as is shown in FIG. 5.

During charging, a positive voltage U_{A2A1} is set. By driving the triac drive circuit, transistor T2 (which, in one embodiment, is an npn transistor) conducts. This causes transistor T1 (which, in one embodiment, is a pnp transistor) to conduct a positive gate current I_{Gate} by way of its emitter-collector junction. This gate current fires the triac, and the corresponding piezoelectric element or bank of elements is charged.

During discharging, a negative voltage U_{A2A1} appears first. Again, driving the triac drive circuit causes transistor T2 to conduct. A negative gate current I_{Gate} flows by way of its emitter-base junction. This gate current causes the triac to fire in the reverse direction and the corresponding piezoelectric element or bank of elements is discharged. During discharging, transistor T1 has no function.

If the triac drive circuit is not driven, neither transistor T1 nor T2 conducts. Thus, a gate current cannot flow and the triac is not fired. In this way, charging or discharging the connected piezoelectric elements of a bank is not possible and the corresponding bank is shut down, thus preventing further failure of the system.

1. An apparatus for driving piezoelectric fuel injector elements divided into a plurality of injector banks, each bank containing at least one piezoelectric element (10, 20), each bank being selected for charging or discharging by a bank-selection switch (S1, S2, S3, S4, S5, S6), characterized in that a bank selection switch includes a triac with a triac drive circuit (312).

2. The apparatus as defined in claim 1, characterized in that an injector bank is shut down when the triac drive circuit (312) is not driven.

3. The apparatus as defined in claim 2 or 3, characterized in that the triac is driven by two transistors.

4. The apparatus as defined in claim 3, characterized in that one transistor is an npn transistor, and the other transistor is a pnp transistor.

5. The apparatus as defined in claim 1, characterized in that a main switch (39) low side is provided for stopping a charging or discharging current when an error occurs.

6. The apparatus as defined in claim 5, characterized in that the main switch (39) is at least one of a MOSFET and an IGBT with reverse diode.

7. A method for driving piezoelectric fuel injector elements divided into a plurality of injector banks, each bank containing at least one piezoelectric element, each bank being selected for charging or discharging by a bank selection-switch, characterized by driving a triac drive circuit.

8. The method as defined in claim 7, characterized by shutting down an injector bank when the triac drive circuit is not driven.

9. The method as defined in claim 7 or 8, characterized in that driving a triac drive circuit includes charging and discharging the circuit.

10. The method as defined in claim 9, characterized in that charging the triac drive circuit includes setting a positive voltage across the triac drive circuit.
